(19) United States
(12) Patent Application Publication
(10) Pub. No.: US 2026/0291508 A1
(43) Pub. Date: Sep. 24, 2026

(54) DEVICE, SYSTEM AND METHODS FOR PLL CONTROL

(71) Applicant: Microchip Technology Inc., Chandler, AZ (US)

(72) Inventors: Krste Mitric, Ottawa (CA); Gary Qu Jin, Kanata (CA); Kamran Rahbar, Kanata (CA); Mark Warriner, Ottawa (CA); Wenbao Wang, Ottawa (CA)

(73) Assignee: Microchip Technology Inc., Chandler, AZ (US)

(21) Appl. No.: 19/364,120

(22) Filed: Oct. 21, 2025

Related U.S. Application Data
(60) Provisional application No. 63/774,821, filed on Mar. 20, 2025.

(51) Int. Cl. H03L 7/093; H03L 7/07; H03L 7/099

(52) U.S. Cl. CPC H03L 7/093; H03L 7/07; H03L 7/0991

(57) ABSTRACT

A device may include a first digital phase-locked loop (DPLL) to generate a first DPLL output clock based on a reference clock and a local oscillator signal. The device may include a second DPLL to generate a second DPLL output clock based on the local oscillator signal and a low-noise oscillator signal. A feedback signal from the first DPLL may be input to the second DPLL, and a loop filter output from the second DPLL may be input to the first DPLL. The device may include a third DPLL to generate a third DPLL output clock based on the local oscillator signal and delayed version of the local oscillator signal. A divider circuit may divide the first DPLL output clock to generate a divided output clock signal.

### PRIORITY

This application claims priority to commonly owned US Provisional Patent Application 63/774,821 filed on March 20, 2025, the entire contents of which are hereby incorporated by reference for all purposes.

### FIELD OF THE INVENTION

The present disclosure relates to a device, system and method for control of a phase-locked loop (PLL) circuit.

### BACKGROUND

To achieve low phase noise (jitter) in ASICs that contain Digital Phase Locked Loops (DPLLs), a high frequency system clock is required. The system clock is used for sampling of external references, and higher the clock frequency, lower the quantization noise that contributes to output clock phase noise. Besides sampling external references, the system clock is used for clocking digital circuitry required for implementing different features that DPLLs have, such as: support for multiple input references and output clocks, multiple DPLLs, reference monitoring, reference switching, holdover, input-to-output alignment, phase and frequency management etc.

The system clock may be generated by an Analog Phase Locked Loop (APLL) form a clock coming from a crystal or MEMS resonator and it has an independent (free running) frequency offset in relation to other external reference clocks, serving as independent baseline timing module. Performance requirements may dictate that a DPLL may consume higher power and larger silicon area to achieve a desired performance.

There is a need for circuits with improved control of PLL circuits with improved phase noise transfer functions.

### SUMMARY

The examples herein enable devices, systems and methods for control of a PLL circuit.

According to one aspect, a device includes a phase acquisition circuit to receive a reference clock, a local oscillator signal and a low-noise oscillator signal. The phase acquisition circuit may sample the reference clock with the local oscillator signal to generate an internal reference signal. The phase acquisition circuit may compare the local oscillator signal to the low-noise oscillator signal to generate an internal low-noise oscillator signal. The device may include a first feedback circuit, a second feedback circuit, and a divider circuit. The first feedback circuit may receive the internal reference signal. The first feedback circuit may include a first digital phase-locked loop (DPLL) circuit, the first DPLL circuit to receive the internal reference signal and to generate a first DPLL output signal. The second feedback circuit may receive the internal low-noise oscillator signal. The first DPLL output signal and the second feedback circuit may include a second DPLL circuit and the second DPLL circuit may receive the internal low-noise oscillator signal and the first DPLL output signal and may generate a second DPLL output signal. The divider circuit to receive the first DPLL output signal and the local oscillator signal and may generate a divided output clock signal.

Aspects as in the preceding paragraph provide a device, wherein the first DPLL circuit comprises a first phase detector to receive the internal reference signal and the output of the first feedback circuit. The first phase detector may generate a first phase detector output based on a comparison of the internal reference signal and the output of the first feedback circuit. The device may include a first loop filter to receive the first phase detector output and to implement a frequency-domain filter operation. The device may include a first adder to receive a first input from the output of the first loop filter and to receive a second input from the second DPLL circuit, and may include a first digitally-controlled oscillator (DCO) to receive input from the first adder and to generate a first DCO output based on the output of the first adder.

Aspects as in at least one of the preceding two paragraphs provide a device, wherein the first loop filter comprises a low-pass filter.

Aspects as in at least one of the preceding three paragraphs provide a device, wherein second DPLL circuit comprises a second phase detector to receive the internal low-noise oscillator signal, an output of the second feedback circuit and the first DPLL output signal. The second phase detector may generate a second phase detector output based on a comparison of the internal low-noise oscillator signal, the output of the second feedback circuit and the first DPLL output signal. The second DPLL circuit may include a second adder to receive input from the output of the second phase detector and from a delayed version of the first DPLL output signal. The second DPLL circuit may include a second loop filter to receive the output of the second adder and to implement a frequency-domain filter operation. The second DPLL circuit may include a second digitally-controlled oscillator (DCO) to receive input from the second loop filter and to generate a second DCO output based on the output of the second loop filter, the second DCO output to be input to the second adder.

Aspects as in at least one of the preceding four paragraphs provide a device, wherein the second loop filter comprises a low-pass filter.

Aspects as in at least one of the preceding five paragraphs provide a device, wherein the divider circuit comprises a hardware divider to generate a divided version of the first DPLL output signal. The divider circuit comprises an adder to receive input from the output of the hardware divider and from the local oscillator signal and to generate the divided output clock signal.

Aspects as in at least one of the preceding six paragraphs provide a device, wherein the divider circuit comprises dividing the first DPLL output by an integer value based on a register setting.

Aspects as in at least one of the preceding seven paragraphs provide a device, wherein the delayed version of the first DPLL output signal to be based on a programmable delay value.

According to one aspect, a device includes a phase acquisition circuit to receive a reference clock, a low-noise oscillator signal and a local oscillator signal. The phase acquisition circuit may generate a delayed version of the local oscillator signal, and the phase acquisition circuit may sample the reference clock with the delayed local oscillator signal to generate an internal reference signal. The phase acquisition circuit may sample the low-noise oscillator signal with the delayed local oscillator signal to generate an internal low-noise oscillator signal. The phase acquisition circuit may sample the local oscillator signal with a delayed version of the local oscillator signal to generate an internal local oscillator signal. The device may include a first feedback circuit, a second feedback circuit, and a divider circuit. The first feedback circuit may receive the internal reference signal, and the first feedback circuit may include a first digital phase-locked loop (DPLL) circuit. The first DPLL circuit may receive the internal reference signal and may generate a first DPLL output signal. The second feedback circuit may receive the internal low-noise oscillator signal and a sampled version of the internal local oscillator signal. The second feedback circuit may include a second DPLL circuit, the second DPLL circuit to receive the internal low-noise oscillator signal and to generate a second DPLL output signal. The divider circuit to receive the first DPLL output signal and the local oscillator signal and to generate a divided output clock signal.

Aspects as in the preceding paragraph provides a device, wherein the first DPLL circuit includes a first phase detector to receive the internal reference signal and the output of the first feedback circuit. The first phase detector may generate a first phase detector output based on a comparison of the internal reference signal and the output of the first feedback circuit. The device may include a first loop filter to receive the first phase detector output and to implement a frequency-domain filter operation. The device may include a first adder to receive a first input from the output of the first loop filter and to receive a second input from the second DPLL circuit, and may include a first digitally-controlled oscillator (DCO) to receive input from the first adder and to generate a first DCO output based on the output of the first adder.

Aspects as in at least one of the preceding two paragraphs provide a device, wherein the first loop filter comprises a low-pass filter.

Aspects as in at least one of the preceding three paragraphs provide a device, wherein the second DPLL circuit includes a second phase detector to receive the internal low-noise oscillator signal and to receive the first DPLL output. The second phase detector may generate a second phase detector output based on a comparison of the internal low-noise oscillator signal and the first DPLL output. The second DPLL circuit may include a second adder to receive input from the output of the second phase detector, from the sampled version of the internal local oscillator signal and from the second DPLL output signal. The second DPLL circuit may include a second loop filter to receive the output of the second adder and to implement a frequency-domain filter operation. The second DPLL circuit may include a second digitally-controlled oscillator (DCO) to receive input from the second loop filter and to generate a second DCO output based on the output of the second loop filter.

Aspects as in at least one of the preceding four paragraphs provide a device, wherein the second loop filter comprises a low-pass filter.

Aspects as in at least one of the preceding five paragraphs provide a device, wherein a hardware divider to generate a divided version of the first DPLL output signal. A delay circuit may generate a delayed version of the local oscillator signal. An adder may receive input from the output of the hardware divider and from the delayed version of the local oscillator signal and may generate the divided output clock signal.

Aspects as in at least one of the preceding six paragraphs provide a device, wherein the hardware divider comprises dividing the first DPLL output by an integer value based on a register setting.

According to one aspect, a method includes steps of: detecting a first phase relationship between an input reference and a local oscillator signal to generate an internal reference signal, detecting a second phase relationship between a low-noise oscillator signal and the local oscillator signal to generate an internal low-noise oscillator signal, generating a third phase relationship between a delayed version of the local oscillator signal and the local oscillator signal, generating a first digital phase-locked-loop (DPLL) output based on the first phase relationship, generating a second DPLL output based on the second phase relationship and based on the third phase relationship, and generating a divided output clock based on the first DPLL output.

Aspects as in the preceding paragraph provide a method, wherein generating a first DPLL output includes detecting a phase relationship between the internal reference signal and the first DPLL output, filtering the phase relationship in a loop filter circuit, and generating the first DPLL output based on the output of the loop filter.

Aspects as in at least one of the preceding two paragraphs provide a method, wherein generating a second DPLL output includes detecting a phase relationship between the internal low-noise oscillator signal and the second DPLL output, filtering the phase relationship in a loop filter circuit, and generating the second DPLL output based on the output of the loop filter.

Aspects as in at least one of the preceding three paragraphs provide a method, wherein generating a divided output clock includes dividing the first DPLL output, and combining the oscillator input and the divided first DPLL output to generate the divided output clock.

Aspects as in at least one of the preceding four paragraphs provide a method, wherein dividing the first DPLL output comprises dividing the first DPLL output by an integer value based on a register setting.

### BRIEF DESCRIPTION OF THE DRAWINGS

A more complete understanding of the disclosure and the advantages thereof may be acquired by referring to the following description, taken in conjunction with the accompanying drawings and wherein:

FIG. 1 illustrates one of various examples of a digital phase-locked loop device.

FIG. 2 illustrates another example of a digital phase-locked loop device.

FIG. 3 illustrates one of various examples of a loop filter for use in a phase-locked loop device.

FIG. 4 illustrates one of various examples of a digitally-controlled oscillator (DCO) circuit.

FIG. 5 illustrates one of various examples of a split-crystal oscillator (XO) digital PLL circuit.

FIG. 6 illustrates one of various examples of frequency response curves for a split-XO digital PLL circuit.

FIG. 7 illustrates one of various examples of a split-XO digital PLL circuit with the system clock locked to the external reference.

FIG. 8 illustrates one of various examples of frequency response curves for the split-XO digital PLL circuit illustrated in FIG. 7.

FIG. 9 illustrates one of various examples of a split-XO digital PLL circuit with feedback compensation.

FIG. 10 illustrates one of various examples of a split-XO digital PLL circuit with XO sampling.

FIG. 11 illustrates one of various examples of a split-XO digital PLL circuit with delayed XO sampling.

FIG. 12 illustrates one of various examples of a split-XO digital PLL with an XO-sampling PLL.

The drawings accompanying and forming part of this specification are included to depict certain aspects of the disclosure. The reference number for any illustrated element that appears in multiple different figures has the same meaning across the multiple figures, and the mention or discussion herein of any illustrated element in the context of any particular figure also applies to each other figure, if any, in which that same illustrated element is shown. The features illustrated in the drawings are not necessarily drawn to scale.

### DETAILED DESCRIPTION

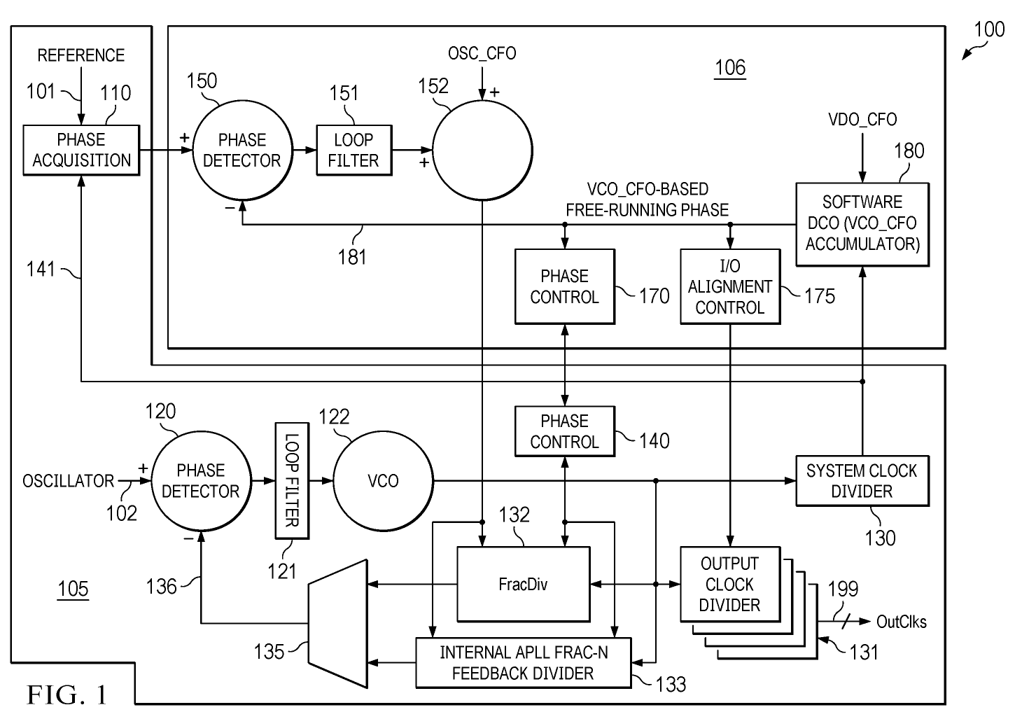

FIG. 1 illustrates one of various examples of a digital phase-locked loop device.

Firmware circuit 106 may be implemented in firmware, and hardware circuit 105 may be implemented in hardware.

A reference clock 101 may be input to a phase acquisition circuit 110. Phase acquisition circuit 110 may include phase comparators, phase detectors and other circuits not specifically mentioned. An output of phase acquisition circuit 110 may be input to phase detector 150. Phase detector 150 may compare the phase of an output of the phase acquisition circuit 110 and the phase of feedback signal 181. The output of phase detector 150 may be input to loop filter 151. The output of loop filter 151 may be input to adder 152. Adder 152 may output a frequency representation to fractional divider 132. An output of phase control circuit 140 may be input to fractional divider circuit 132. An output of phase control circuit 140 may be input to analog PLL divider 133. An output of analog PLL divider may be input to multiplexer 135. An output of adder 152 may be input to analog PLL divider 133. Fractional divider 132 may output a signal to multiplexer 135. Fractional divider 132 may output a signal to output clock divider 131.

Oscillator signal 102 may be input to phase detector 120. Phase detector 120 may receive input from feedback signal 136. An output of phase detector 120 may be input to loop filter 121. An output of loop filter 121 may be input to voltage-controlled oscillator (VCO) 122. An output of VCO 122 may be input to system clock divider 130. An output of system clock divider 130 may be input to phase acquisition circuit 110 via feedback signal 141. An output of system clock divider 130 may be input to digitally-controlled oscillator (DCO) 180. DCO 180 may output feedback signal 181.

Feedback signal 181 may be input to a first phase control circuit 170. An output of first phase control circuit 170 may be output to second phase control circuit 140. Feedback signal 181 may be input to I/O alignment control circuit 175. An output of I/O alignment control circuit 175 may be input to output clock divider 131, and output clock divider may output a divided output clock signal 199 based at least on an output of I/O alignment control circuit 175.

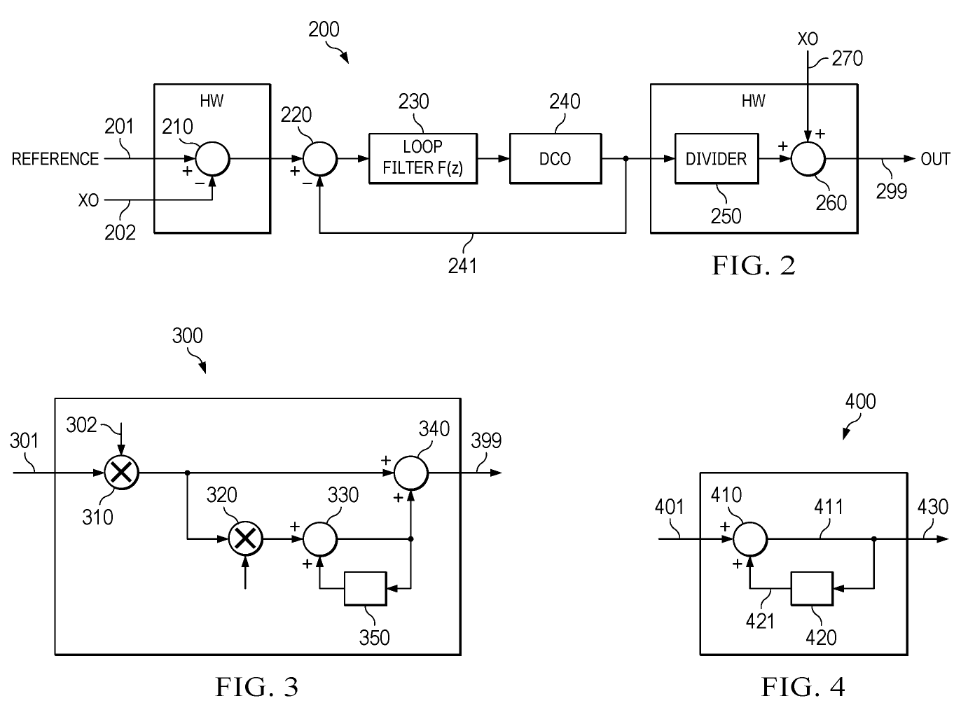

FIG. 2 illustrates another example of a digital phase-locked loop device 200.

A reference clock 201 may be input to device 200. An oscillator signal 202 may be input to device 200. Reference clock 201 and oscillator signal 202 may be input to phase comparator 210, and, at phase comparator 210, oscillator signal 202 may sample reference clock 201 and phase comparator 210 may output a signal representing the phase difference between reference clock 201 and oscillator signal 202.

An output of phase comparator 210 may be input to phase detector 220. Phase detector 220 may compare the output of phase comparator 210 and feedback signal 241 and may output a phase difference between the output of phase comparator 210 and feedback signal 241. An output of phase detector 220 may be input to loop filter 230, and an output of loop filter 230 may be input to digitally-controlled oscillator (DCO) 240. DCO 240 may output an oscillator signal based on the output of the loop filter. An output of DCO 240 may comprise feedback signal 241. An output of DCO 240 may be input to divider 250. Divider 250 may implement an integer divider, and may output a divided version of feedback signal 241. The divided version of feedback signal 241 may be input to adder 260. Oscillator signal 202 may be input to adder 260, and adder 260 may generate a divided output clock signal 299 based on the divided version of feedback signal 241 and based on oscillator signal 202.

FIG. 3 illustrates one of various examples of a loop filter 300 for use in a phase-locked loop device. Loop filter 300 may represent one of various examples of loop filter 230 as described and illustrated in reference to FIG. 2. Loop filter 300 may represent one of various examples of loop filter 121 and loop filter 151 as described and illustrated in reference to FIG. 1.

Input signal 301 may be input to multiplier 310. A proportional path control value 302 may be input to multiplier 310. Proportional path control value 302 may control the bandwidth of loop filter 300.

An output of multiplier 310 may be input to adder 340. An output of multiplier 310 may be input to multiplier 320. A damping factor control 325 may be input to multiplier 320 and may determine a damping factor in the phase-locked loop device. An output of multiplier 310 may be input to adder 330. An output of adder 330 may be input to adder 340 and may be input to delay circuit 350. Delay circuit 350 may introduce a delay value. The delay value may be a fixed delay or a variable delay and may be related to a clock signal. The delay value may be an integer number of periods of the clock signal. An output of adder 340 may be loop filter output 399.

FIG. 4 illustrates one of various examples of a digitally-controlled oscillator (DCO) circuit 400.

An input value 401 may be input to adder 410. A feedback value 421 may be input to adder 410. Adder output 411 may be a sum of input value 401 and feedback value 421. Adder output 411 may be input to delay circuit 420 to generate feedback value 421. Adder output 411 may be DCO output 430. In one of various examples, delay circuit 420 may implement a programmable delay value.

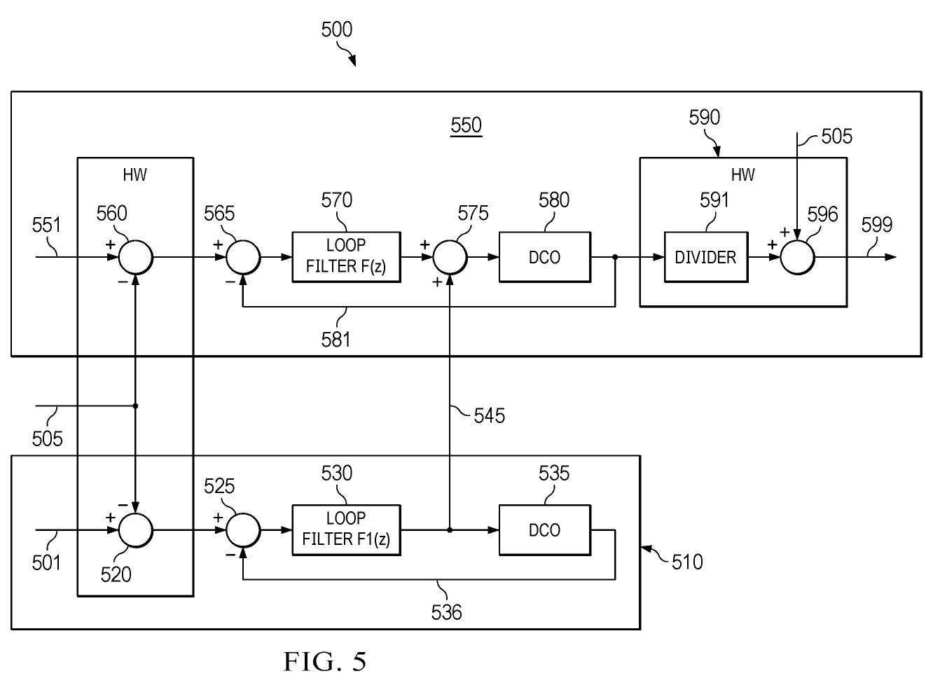

FIG. 5 illustrates one of various examples of a split-crystal oscillator (XO) digital PLL circuit 500.

Reference clock 551, local oscillator signal 505 and low-noise oscillator signal 501 may be input to circuit 500. Reference clock 551 may be input to first phase comparator 560. At first phase comparator 560, local oscillator signal 505 may sample reference clock 551 and may output a phase difference between reference clock 551 and local oscillator signal 505. An output of first phase comparator 560 may be an internal reference signal and may be input to first phase detector 565. Feedback signal 581 may be input to first phase detector 565. First phase detector 565 may compare feedback signal 581 and the internal reference signal and an output of first phase detector 565 may represent a phase difference between the internal reference signal and the feedback signal 581.

The output of first phase detector 565 may be input to first loop filter 570. First loop filter 570 may implement a frequency-domain filter operation and may filter the output of first phase detector 565 based on a predetermined frequency profile. First loop filter 570 may implement a low-pass filter, a band-pass filter, a high-pass filter, a band-stop filter or another type of filter not specifically mentioned.

An output of first loop filter 570 may be input to first adder 575. An output of second loop filter 530 may be input to first adder 575. First adder 575 may add an output of first loop filter 570 and an output of second loop filter 530 and an output of first adder 575 may be input to first DCO 580. An output of first DCO 580 may be a first DCO output, and may be feedback signal 581. Feedback signal 581 may be input to divider circuit 590. Divider circuit 590 may include hardware divider 591 and hardware divider 591 may apply an integer division ratio and may output a divided version of feedback signal 581. The integer division value may be based on a register setting. An output of hardware divider 591 may be input to adder 596. Local oscillator signal 505 may be input to adder 596, and the output of adder 596 may be divided output clock signal 599. Hardware divider 591 and adder 596 may be implemented in hardware.

Local oscillator signal 505 may be input to second phase comparator 520. Low-noise oscillator signal 501 may be input to second phase comparator 520. At second phase comparator 520, local oscillator signal 505 may sample low-noise oscillator signal 501 and may output a phase difference between low-noise oscillator signal 501 and local oscillator signal 505. An output of second phase comparator 520 may be an internal low-noise oscillator signal and may be input to second phase detector 525. Feedback signal 536 may be input to second phase detector 525. Second phase detector 525 may compare feedback signal 536 and the internal low-noise oscillator signal and an output of second phase detector 525 may represent a phase difference between the internal low-noise oscillator signal and the feedback signal 536.

The output of second phase detector 525 may be input to second loop filter 530. Second loop filter 530 may implement a frequency-domain filter operation and may filter the output of second phase detector 525 based on a predetermined frequency profile. Second loop filter 530 may implement a low-pass filter, a band-pass filter, a high-pass filter, a band-stop filter or another type of filter not specifically mentioned. An output of second loop filter 530 may be input to first adder 575 and may be input to second DCO 535. An output of second DCO 535 and may be feedback signal 536.

An output of first DCO 580 may be a first DPLL output signal and an output of second DCO 535 may be a second DPLL output signal.

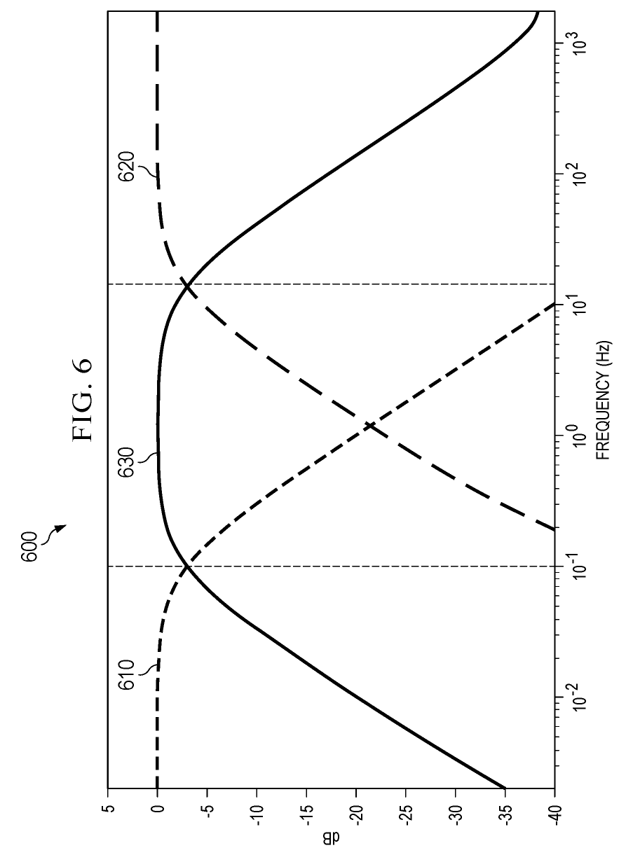

FIG. 6 illustrates one of various examples of frequency response curves for a split-XO digital PLL circuit. FIG. 6 may illustrate frequency response curves as in a digital PLL circuit as described and illustrated in reference to FIG. 5.

Trace 610 represents one of various examples of a transfer function from reference clock 551 to divided output clock signal 599. As illustrated in FIG. 6, trace 610 shows a low-pass transfer function from reference clock 551 to divided output clock signal 599, filtering out high-frequency noise in reference clock 551.

Trace 620 represents one of various examples of a transfer function from local oscillator signal 505 to divided output clock signal 599. As illustrated in FIG. 6, trace 620 shows a high-pass transfer function from local oscillator signal 505 to divided output clock signal 599, filtering out low-frequency noise in local oscillator signal 505.

Trace 630 represents one of various examples of a transfer function from low-noise oscillator signal 501 to divided output clock signal 599. As illustrated in FIG. 6, trace 630 shows a band-pass transfer function from low-noise oscillator signal 501 to divided output clock signal 599, filtering out high-frequency and low-frequency noise in low-noise oscillator signal 501.

The specific frequency profiles, cutoff frequencies and attenuations illustrated in FIG. 6 are for illustrative purposes and are not limiting. Other examples may include different frequency profiles, cutoff frequencies and attenuations.

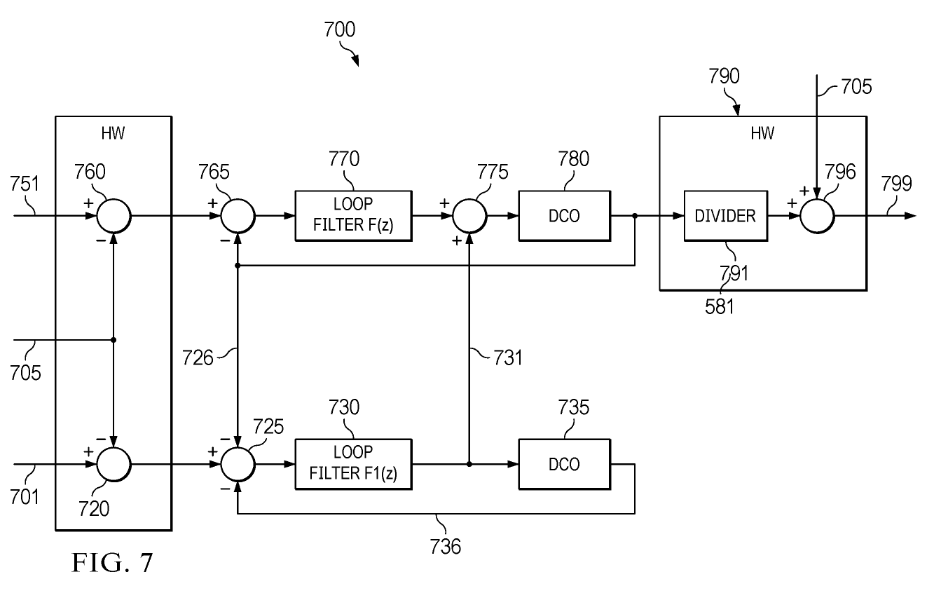

FIG. 7 illustrates one of various examples of a split-XO digital PLL circuit 700 with the system clock locked to the external reference.

Reference clock 751, local oscillator signal 705 and low-noise oscillator signal 701 may be input to circuit 700. Reference clock 751 may be input to first phase comparator 760. Local oscillator signal 705 may be input to first phase comparator 760. At first phase comparator 760, local oscillator signal 705 may sample reference clock 751 and may output a phase difference between reference clock 751 and local oscillator signal 705. An output of first phase comparator 760 may comprise an internal reference signal may be input to first phase detector 765. Feedback signal 726 may be input to first phase detector 765. First phase detector 765 may compare feedback signal 726 and the internal reference signal and an output of first phase detector 765 may represent a phase difference between the internal reference signal and the feedback signal 726.

The output of first phase detector 765 may be input to first loop filter 770. First loop filter 770 may implement a frequency-domain filter operation and may filter the output of first phase detector 765 based on a predetermined frequency profile. First loop filter 770 may implement a low-pass filter, a band-pass filter, a high-pass filter, a band-stop filter or another type of filter not specifically mentioned.

An output of first loop filter 770 may be input to first adder 775. An output 731 of second loop filter 730 may be input to first adder 775. An output of first adder 775 may be input to first DCO 780. An output of first DCO 780 may be a first DCO output, and may be feedback signal 726. An output of first DCO 780 may be a first DPLL output signal. The first DPLL output signal may be input to divider circuit 790. Divider circuit 790 may include hardware divider 791 and may apply an integer division ratio and may output a divided version of the first DPLL output signal. The integer division value may be based on a register setting. An output of hardware divider 791 may be input to adder 796. Local oscillator signal 705 may be input to adder 796, and the output of adder 796 may be divided output clock signal 799. Hardware divider 791 and adder 796 may be implemented in hardware.

Local oscillator signal 705 may be input to second phase comparator 720. Low-noise oscillator signal 701 may be input to second phase comparator 720. At second phase comparator 720, local oscillator signal 705 may sample low-noise oscillator signal 701 and may output a phase difference between low-noise oscillator signal 701 and local oscillator signal 705. An output of second phase comparator 720 may be an internal low-noise oscillator signal and may be input to second phase detector 725. Feedback signal 736 and feedback signal 726 may be input to second phase detector 725. Second phase detector 725 may compare the internal low-noise oscillator signal, feedback signal 726, and feedback signal 736 and may output a difference between the internal low-noise oscillator signal and the feedback signals 736 and 726.

The output of second phase detector 725 may be input to second loop filter 730. Second loop filter 730 may implement a frequency-domain filter operation and may filter the output of second phase detector 725 based on a predetermined frequency profile. Second loop filter 730 may implement a low-pass filter, a band-pass filter, a high-pass filter, a band-stop filter or another type of filter not specifically mentioned. An output of second loop filter 730 may be input to first adder 775 and to second DCO 735. An output of second DCO 735 may be an oscillator signal, and may be feedback signal 736. An output of second DCO 735 may be second DPLL output signal.

An output of first DCO 780 may be a first DPLL output signal and an output of second DCO 735 may be a second DPLL output signal.

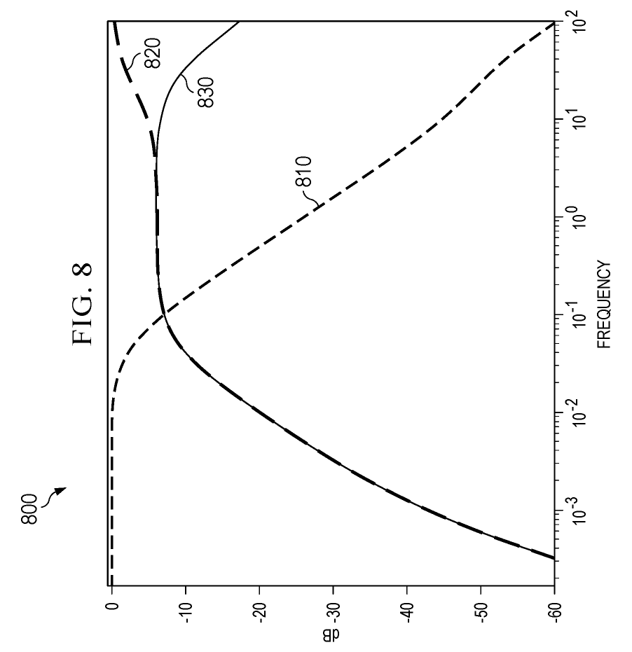

FIG. 8 illustrates one of various examples of frequency response curves for the split-XO digital PLL circuit illustrated in FIG. 7. FIG. 8 may illustrate frequency response curves as in a digital PLL circuit as described and illustrated in reference to FIG. 7.

Trace 810 represents one of various examples of a transfer function from reference clock 751 to divided output clock signal 799. As illustrated in FIG. 8, trace 810 shows a low-pass transfer function from reference clock 751 to divided output clock signal 799, filtering out high-frequency noise in reference clock 751.

Trace 820 represents one of various examples of a transfer function from local oscillator signal 705 to divided output clock signal 799. As illustrated in FIG. 8, trace 820 shows a high-pass transfer function from local oscillator signal 705 to divided output clock signal 799, filtering out low-frequency noise in local oscillator signal 705.

Trace 830 represents one of various examples of a transfer function from low-noise oscillator signal 701 to divided output clock signal 799. As illustrated in FIG. 8, trace 830 shows a band-pass transfer function from low-noise oscillator signal 701 to divided output clock signal 799, filtering out high-frequency and low-frequency noise in low-noise oscillator signal 701.

The specific frequency profiles, cutoff frequencies and attenuations illustrated in FIG. 8 are for illustrative purposes and are not limiting. Other examples may include different frequency profiles, cutoff frequencies and attenuations.

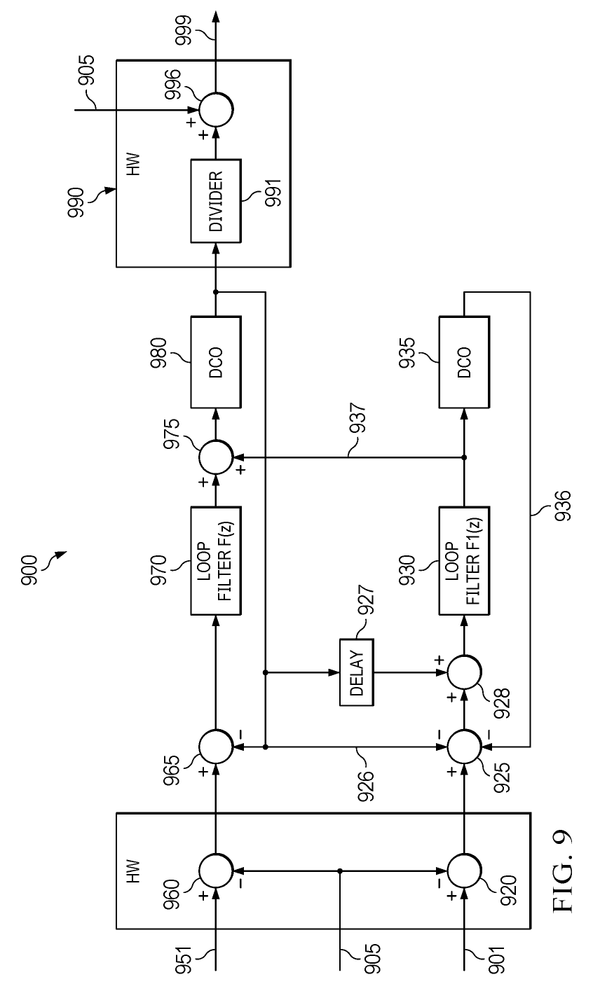

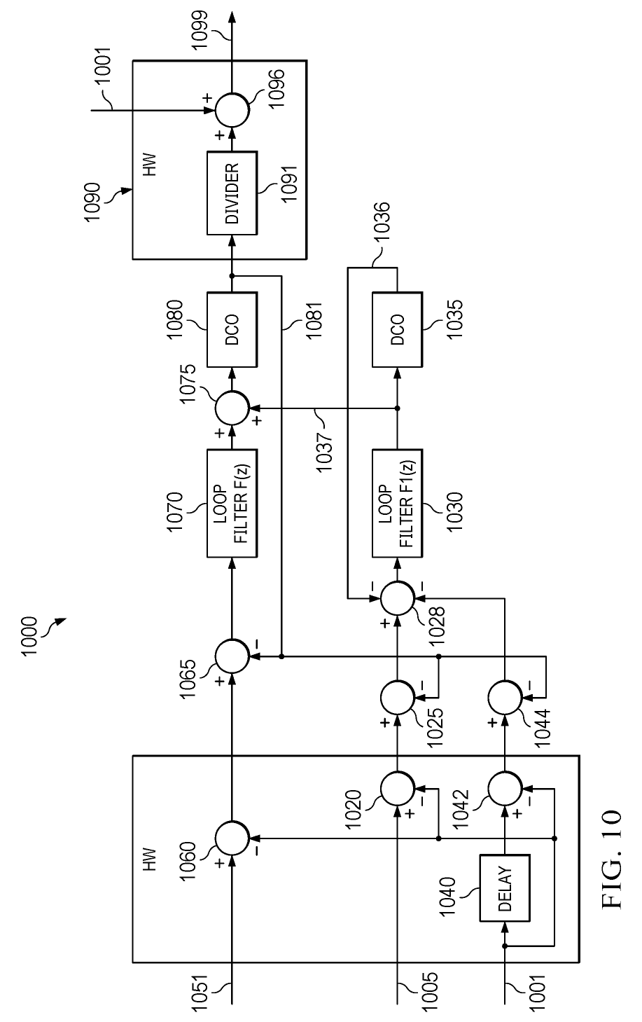

FIG. 9 illustrates one of various examples of a split-XO digital PLL circuit 900 with feedback compensation.

Reference clock 951, local oscillator signal 905 and low-noise oscillator signal 901 may be input to circuit 900. Reference clock 951 and local oscillator signal 905 may be input to first phase comparator 960. At first phase comparator 960, local oscillator signal 905 may sample reference clock 951 and may output a phase difference between reference clock 951 and local oscillator signal 905. An output of first phase comparator 960 may be an internal reference signal and may be input to first phase detector 965. Feedback signal 926 may be input to first phase detector 965. At first phase detector 965, feedback signal 926 may be compared to the internal reference signal and an output of first phase detector 965 may represent a phase difference between the internal reference signal and the feedback signal 926.

An output of first phase detector 965 may be input to first loop filter 970. First loop filter 970 may implement a frequency-domain filter operation and may filter the output of first phase detector 965 based on a predetermined frequency profile F(z). First loop filter 970 may implement a low-pass filter, a band-pass filter, a high-pass filter, a band-stop filter or another type of filter not specifically mentioned.

An output of first loop filter 970 may be input to first adder 975. An output 937 of second loop filter 930 may be input to first adder 975. An output of first adder 975 may be input to DCO 980. An output of DCO 980 may be a first DPLL output signal, and may be feedback signal 926. The first DPLL output signal may be input to divider circuit 990. Divider circuit 990 may include hardware divider 991 to apply an integer division ratio and may output a divided version of the first DPLL output signal. The integer division value may be based on a register setting. An output of hardware divider 991 may be input to adder 996. Local oscillator signal 905 may be input to adder 996, and the output of adder 996 may be divided output clock signal 999. Hardware divider 991 and adder 996 may be implemented in hardware.

First phase detector 965, first loop filter 970, first adder 975 and first DCO 980 may comprise a first DPLL circuit. The first DPLL circuit may contain a first feedback circuit.

Local oscillator signal 905 may be input to second phase comparator 920 and low-noise oscillator signal 901 may be input to second phase comparator 920. At second phase comparator 920, local oscillator signal 905 may sample low-noise oscillator signal 901 and may output a phase difference between low-noise oscillator signal and local oscillator signal 905. An output of second phase comparator 920 may be an internal low-noise oscillator signal and may be input to second phase detector 925. Feedback signal 936 and feedback signal 926 may be input to second phase detector 925, and an output of second phase detector 925 may represent a phase difference between the internal low-noise oscillator signal and the feedback signals 936 and 926.

An output of second phase detector 925 may be input to second adder 928. Feedback signal 926 may be input to delay circuit 927, and the output of delay circuit 927 may be input to second adder 928. In one of various examples, delay circuit 927 may implement a programmable delay value, the programmable delay value equal to D. An output of second adder 928 may be input to second loop filter 930. Second loop filter 930 may implement a frequency-domain filter operation and may filter the output of second adder 928 based on a predetermined frequency profile F1(z). Second loop filter 930 may implement a low-pass filter, a band-pass filter, a high-pass filter, a band-stop filter or another type of filter not specifically mentioned. An output 937 of second loop filter 930 may be input to first adder 975 and to second DCO 935. An output of second DCO 935 may be a second DPLL output signal, and may be feedback signal 936.

Second phase detector 925, second loop filter 930, second adder 928 and second DCO 935 may comprise a second DPLL circuit. The second DPLL circuit may contain a second feedback circuit.

First phase comparator 960 and second phase comparator 920 may comprise a phase acquisition circuit.

FIG. 10 illustrates one of various examples of a split-XO digital PLL circuit 1000 with XO sampling.

Reference clock 1051, low-noise oscillator signal 1005 and local oscillator signal 1001 may be input to circuit 1000. Reference clock 1051 and local oscillator signal 1001 may be input to first phase comparator 1060. At first phase comparator 1060, local oscillator signal 1001 may sample reference clock 1051 and may output a phase difference between reference clock 1051 and local oscillator signal 1001. An output of first phase comparator 1060 may be an internal reference signal and may be input to first phase detector 1065. Feedback signal 1081 may be input to first phase detector 1065. At first phase detector 1065, feedback signal 1081 may be compared to the internal reference signal and an output of first phase detector 1065 may represent a phase difference between the internal reference signal and the feedback signal 1081.

The output of first phase detector 1065 may be input to first loop filter 1070. First loop filter 1070 may implement a frequency-domain filter operation and may filter the output of first phase detector 1065 based on a predetermined frequency profile, F(z). First loop filter 1070 may implement a low-pass filter, a band-pass filter, a high-pass filter, a band-stop filter or another type of filter not specifically mentioned.

An output of first loop filter 1070 may be input to first adder 1075. An output 1037 of second loop filter 1030 may be input to first adder 1075. An output of first adder 1075 may be input to first DCO 1080. An output of first DCO 1080 may be a first DPLL output signal, and may be feedback signal 1081. The first DPLL output signal may be input to divider circuit 1090. Divider circuit 1090 may include hardware divider 1091 and hardware divider 1091 may apply an integer division ratio and may output a divided version of the first DPLL output signal. The integer division value may be based on a register setting. An output of hardware divider 1091 may be input to adder 1096. Local oscillator signal 1001 may be input to adder 1096, and the output of adder 1096 may be divided output clock signal 1099. Divider 1091 and adder 1096 may be implemented in hardware.

First phase detector 1065, first loop filter 1070, first adder 1075 and first DCO 1080 may comprise a first DPLL circuit. The first DPLL circuit may contain a first feedback circuit.

Low-noise oscillator signal 1005 may be input to second phase comparator 1020. Local oscillator signal 1001 may be input to second phase comparator 1020. At second phase comparator 1020, local oscillator signal 1001 may sample low-noise oscillator signal 1005 and may output a phase difference between low-noise oscillator signal 1005 and local oscillator signal 1001. An output of second phase comparator 1020 may be an internal low-noise oscillator signal and may be input to second phase detector 1025. Feedback signal 1081 may be input to second phase detector 1025. Second phase detector 1025 may compare feedback signal 1081 and the internal low-noise oscillator signal and an output of second phase detector 1025 may represent a phase difference between the low-noise oscillator signal and the feedback signal 1081.

An output of second phase detector 1025 may be a sampled version of the internal low-noise oscillator signal and may be input to second adder 1028. An output of third phase detector 1044 and feedback signal 1036 may be input to second adder 1028 and an output of second adder 1028 may represent a phase difference between an output of second phase detector 1025, the output of third phase detector 1044, and feedback signal 1036.

An output of second adder 1028 may be input to second loop filter 1030. Second loop filter 1030 may implement a frequency-domain filter operation and may filter the output of second adder 1028 based on a predetermined frequency profile F1(z). Second loop filter 1030 may implement a low-pass filter, a band-pass filter, a high-pass filter, a band-stop filter or another type of filter not specifically mentioned. An output 1037 of second loop filter 1030 may be input to first adder 1075 and to second DCO 1035. An output of second DCO 1035 may be an oscillator signal, and may be feedback signal 1036. An output of second DCO 1035 may be a second DPLL output signal.

Local oscillator signal 1001 may be input to delay circuit 1040. In one of various examples, delay circuit 1040 may implement a programmable delay value, the delay value equal to D. Local oscillator signal 1001 and an output of delay circuit 1040 may be input to third phase comparator 1042. At third phase comparator 1042, local oscillator signal 1001 may sample the output of delay circuit 1040 and may output a phase difference between local oscillator signal 1001 and the output of delay circuit 1040. An output of third phase comparator 1042 may be an internal local oscillator signal and may be input to third phase detector 1044. Feedback signal 1081 may be input to third phase detector 1044, and an output of third phase detector 1044 may represent a phase difference between the third phase comparator 1042 output and the feedback signal 1081. An output of third phase detector 1044 may be input to second adder 1028.

Second phase detector 1025, second loop filter 1030, second adder 1028 and second DCO 1035 may comprise a second DPLL circuit. The second DPLL circuit may contain a second feedback circuit.

First phase comparator 1060, second phase comparator 1020, third phase comparator 1042, and delay circuit 1040 may comprise a phase acquisition circuit.

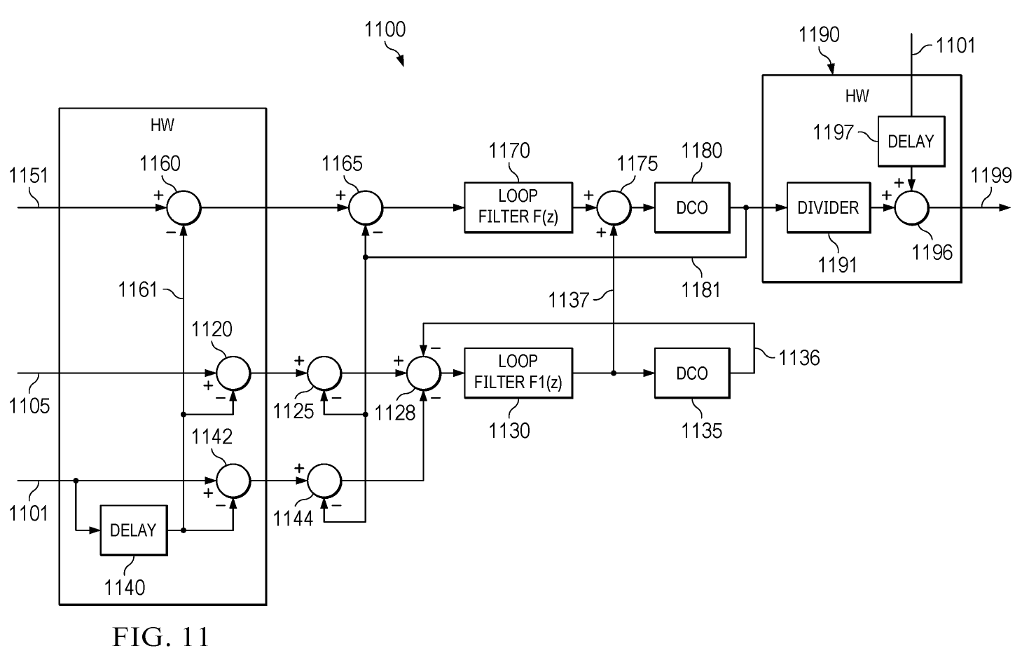

FIG. 11 illustrates one of various examples of a split-XO digital PLL circuit 1100 with delayed XO sampling.

Reference clock 1151, low-noise oscillator signal 1105 and local oscillator signal 1101 may be input to circuit 1100. Reference clock 1151 may be input to first phase comparator 1160. Local oscillator signal 1101 may be input to delay circuit 1140, and a delayed local oscillator signal 1161 may be input to first phase comparator 1160. In one of various examples, delay circuit 1140 may implement a programmable delay value, the delay value equal to D. At first phase comparator 1160, delayed local oscillator signal 1161 may sample reference clock 1151 and may output an internal reference signal which may represent a phase difference between reference clock 1151 and delayed local oscillator signal 1161. An output of first phase comparator 1160 may be input to first phase detector 1165. Feedback signal 1181 may be input to first phase detector 1165. First phase detector 1165 may compare feedback signal 1181 and the internal reference signal and an output of first phase detector 1165 may represent a phase difference between the internal reference signal and the feedback signal 1181.

The output of first phase detector 1165 may be input to first loop filter 1170. First loop filter 1170 may implement a frequency-domain filter operation and may filter the output of first phase detector 1165 based on a predetermined frequency profile, F(z). First loop filter 1170 may implement a low-pass filter, a band-pass filter, a high-pass filter, a band-stop filter or another type of filter not specifically mentioned.

An output of first loop filter 1170 may be input to first adder 1175. An output 1137 of second loop filter 1130 may be input to first adder 1175. An output of first adder 1175 may be input to first DCO 1180. An output of first DCO 1180 may be a first DCO output, and may be feedback signal 1181. An output of first DCO 1180 may be a first DPLL output signal. The first DPLL output signal may be input to divider circuit 1190. Divider circuit 1190 may include hardware divider 1191 may apply an integer division ratio and may output a divided version of feedback signal 1181. The integer division value may be based on a register setting. An output of hardware divider 1191 may be input to adder 1196. Local oscillator signal 1101 may be input to delay circuit 1197, and an output of delay circuit 1197 may be input to adder 1196. Delay circuit 1197 may generate a delay of value D, equal to the delay value of delay circuit 1140. The output of adder 1196 may be divided output clock signal 1199. Hardware divider 1091, delay circuit 1197 and adder 1196 may be implemented in hardware. In one of various examples, delay circuit 1197 may implement a programmable delay value.

First phase detector 1165, first loop filter 1170, first adder 1175 and first DCO 1180 may comprise a first DPLL circuit. The first DPLL circuit may contain a first feedback circuit.

Low-noise oscillator signal 1105 may be input to second phase comparator 1120. Delayed local oscillator signal 1161 may be input to second phase comparator 1120. At second phase comparator 1120, delayed local oscillator signal 1161 may sample low-noise oscillator signal 1105 and may output an internal low-noise oscillator signal which may represent a phase difference between low-noise oscillator signal 1105 and delayed local oscillator signal 1161. An output of second phase comparator 1120 may be an internal low-noise oscillator signal and may be input to second phase detector 1125. Feedback signal 1181 may be input to second phase detector 1125. Second phase detector 1125 may compare feedback signal 1181 and the internal low-noise oscillator signal and an output of second phase detector 1125 may represent a phase difference between the internal low-noise oscillator signal and the feedback signal 1181.

An output of second phase detector 1125 may be a sampled version of the internal low-noise oscillator signal and may be input to second adder 1128. An output of third phase detector 1144 and feedback signal 1136 may be input to second adder 1128. Second adder 1128 may compare an output of third phase detector 1134, an output of second phase detector 1125 and feedback signal 1136.

An output of second adder 1128 may be input to second loop filter 1130. Second loop filter 1130 may implement a frequency-domain filter operation and may filter the output of second adder 1128 based on a predetermined frequency profile F1(z). Second loop filter 1130 may implement a low-pass filter, a band-pass filter, a high-pass filter, a band-stop filter or another type of filter not specifically mentioned. An output 1137 of second loop filter 1130 may be input to first adder 1175 and to second DCO 1135. An output of second DCO 1135 may be an oscillator signal, and may be feedback signal 1136. An output of second DCO 1135 may be a second DPLL output signal.

Local oscillator signal 1101 and delayed local oscillator signal 1161 may be input to third phase comparator 1142. At third phase comparator 1142, delayed local oscillator signal 1161 may sample local oscillator signal 1101 and may output an internal local oscillator signal which may represent a phase difference between local oscillator signal 1101 and delayed local oscillator signal 1161. An output of third phase comparator 1142 may be an internal local oscillator signal and may be input to third phase detector 1144. Feedback signal 1181 may be input to third phase detector 1144. Third phase detector 1144 may compare feedback signal 1181 and the internal local oscillator signal and an output of third phase detector 1144 may represent a phase difference between the internal local oscillator signal and the feedback signal 1181. An output of third phase detector 1144 may be a sampled version of the internal local oscillator signal and may be input to second adder 1128.

Second phase detector 1125, second loop filter 1130, second adder 1128 and second DCO 1135 may comprise a second DPLL circuit. The second DPLL circuit may contain a second feedback circuit.

First phase comparator 1160, second phase comparator 1120, third phase comparator 1142 and delay circuit 1140 may comprise a phase acquisition circuit.

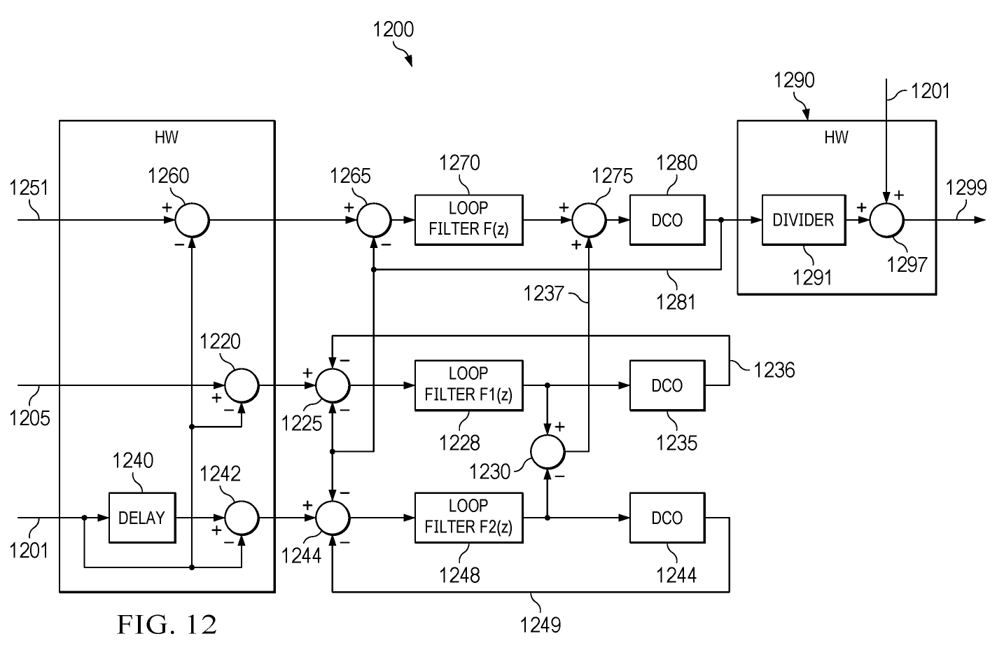

FIG. 12 illustrates one of various examples of a split-XO digital PLL 1200 with an XO-sampling PLL.

Reference clock 1251, low-noise oscillator signal 1205 and local oscillator signal 1201 may be input to digital PLL 1200. Reference clock 1251 may be input to first phase comparator 1260. Local oscillator signal 1201 may be input to delay circuit 1240, and local oscillator signal 1201 may be input to first phase comparator 1260. At first phase comparator 1260, local oscillator signal 1201 may sample reference clock 1251 and may output an internal reference signal which may represent a phase difference between reference clock 1251 and local oscillator signal 1201. An output of first phase comparator 1260 may be input to first phase detector 1265. Feedback signal 1281 may be input to first phase detector 1265. First phase detector 1265 may compare feedback signal 1281 and the internal reference signal and an output of first phase detector 1265 may represent a phase difference between the internal reference signal and the feedback signal 1281.

The output of first phase detector 1265 may be input to first loop filter 1270. First loop filter 1270 may implement a frequency-domain filter operation and may filter the output of first phase detector 1265 based on a predetermined frequency profile, F(z). First loop filter 1270 may implement a low-pass filter, a band-pass filter, a high-pass filter, a band-stop filter or another type of filter not specifically mentioned.

An output of first loop filter 1270 may be input to first adder 1275. Output 1237 of second adder 1230 may be input to first adder 1275. An output of first adder 1275 may be input to first DCO 1280. An output of first DCO 1280 may be a first DCO output, and may be feedback signal 1281. An output of first DCO 1280 may be a first DPLL output signal. The first DPLL output signal may be input to divider circuit 1290. Divider circuit 1290 may include hardware divider 1291 and hardware divider 1291 may apply an integer division ratio and may output a divided version of first DPLL output signal . The integer division value may be based on a register setting. An output of hardware divider 1291 may be input to adder 1297. Local oscillator signal 1201 may be input to adder 1297. The output of adder 1297 may be divided output clock signal 1299. Hardware divider 1291 and adder 1297 may be implemented in hardware.

First phase detector 1265, first loop filter 1270, first adder 1275 and first DCO 1280 may comprise a first DPLL circuit. The first DPLL circuit may contain a first feedback circuit.

Low-noise oscillator signal 1205 may be input to second phase comparator 1220. Local oscillator signal 1201 may be input to second phase comparator 1220. At second phase comparator 1220, local oscillator signal 1201 may sample low-noise oscillator signal 1205 and may output an internal low-noise oscillator signal which may represent a phase difference between low-noise oscillator signal 1205 and local oscillator signal 1201. The internal low-noise oscillator signal may be input to second phase detector 1225. Feedback signal 1236 and feedback signal 1281 may be input to second phase detector 1225. Second phase detector 1225 may compare feedback signal 1281, feedback signal 1236 and the internal low-noise oscillator signal and an output of second phase detector 1225 may represent a phase difference between the internal low-noise oscillator signal and the feedback signals 1281 and 1236.

An output of second phase detector 1225 may be input to second loop filter 1228. Second loop filter 1228 may implement a frequency-domain filter operation and may filter the output of second phase detector 1225 based on a predetermined frequency profile F1(z). Second loop filter 1228 may implement a low-pass filter, a band-pass filter, a high-pass filter, a band-stop filter or another type of filter not specifically mentioned. An output of second loop filter 1228 may be input to second DCO 1235 and to second adder 1230 and an output of third loop filter 1248 may be input to second adder 1230. Output 1237 of second adder 1230 may be input to first adder 1275. An output of second loop filter 1228 may be input to second adder 1230 and to second DCO 1235. An output of second DCO 1235 may be an oscillator signal, and may be feedback signal 1236. An output of second DCO 1235 may be a second DPLL output signal.

Second phase detector 1225, second loop filter 1228, second adder 1230 and second DCO 1235 may comprise a second DPLL circuit. The second DPLL circuit may contain a second feedback circuit.

Local oscillator signal 1201 may be input to delay circuit 1240 and may output a delayed local oscillator signal. In one of various examples, delay circuit 1240 may implement a programmable delay value. In one of various examples, delay circuit 1240 may implement a programmable delay value, the delay value equal to D. Local oscillator signal 1201 and the delayed local oscillator signal may be input to third phase comparator 1242. At third phase comparator 1242, local oscillator signal 1201 may sample the delayed local oscillator signal and may output an internal local oscillator signal which may represent a phase difference between local oscillator signal 1201 and the delayed local oscillator signal. An output of third phase comparator 1242 may be an internal local oscillator signal and may be input to third phase detector 1244. Feedback signals 1281 and 1249 may be input to third phase detector 1244. Third phase detector 1244 may compare feedback signal 1281, feedback signal 1249 and the internal local oscillator signal and an output of third phase detector 1244 may represent a phase difference between the internal local oscillator signal and the feedback signals 1281 and 1249.

An output of third phase detector 1244 may be input to third loop filter 1248. Third loop filter 1248 may filter the output of third phase detector 1244 based on a predetermined frequency profile, F2(z). Third loop filter 1248 may implement a low-pass filter, a band-pass filter, a high-pass filter, a band-stop filter or another type of filter not specifically mentioned.

An output of third loop filter 1248 may be input to second adder 1230. An output of third loop filter 1248 may be input to third DCO 1244. Third DCO 1244 may generate an oscillator signal, the oscillator signal comprising feedback signal 1249.

First phase comparator 1260, second phase comparator 1220, third phase comparator 1242 and delay circuit 1240 may comprise a phase acquisition circuit.

Although examples have been described above, other variations and examples may be made from this disclosure without departing from the spirit and scope of these disclosed examples.

1. A device comprising:
a phase acquisition circuit to receive a reference clock, a local oscillator signal and a low-noise oscillator signal, the phase acquisition circuit to sample the reference clock with the local oscillator signal to generate an internal reference signal and the phase acquisition circuit to compare the local oscillator signal to the low-noise oscillator signal to generate an internal low-noise oscillator signal;
a first feedback circuit;
a second feedback circuit; and
a divider circuit,
wherein the first feedback circuit to receive the internal reference signal and the first feedback circuit comprising:
a first digital phase-locked loop (DPLL) circuit, the first DPLL circuit to receive the internal reference signal and to generate a first DPLL output signal,
wherein the second feedback circuit to receive the internal low-noise oscillator signal, the first DPLL output signal and the second feedback circuit comprising:
a second DPLL circuit, the second DPLL circuit to receive the internal low-noise oscillator signal and the first DPLL output signal and to generate a second DPLL output signal, and
wherein the divider circuit to receive the first DPLL output signal and the local oscillator signal and to generate a divided output clock signal.

2. The device as claimed in claim 1, wherein the first DPLL circuit comprises:
a first phase detector to receive the internal reference signal and the output of the first feedback circuit, the first phase detector to generate a first phase detector output based on a comparison of the internal reference signal and the output of the first feedback circuit;
a first loop filter to receive the first phase detector output and to implement a frequency-domain filter operation;
a first adder to receive a first input from the output of the first loop filter and to receive a second input from the second DPLL circuit; and
a first digitally-controlled oscillator (DCO) to receive input from the first adder and to generate a first DCO output based on the output of the first adder.

3. The device as claimed in claim 2, wherein the first loop filter comprises a low-pass filter.

4. The device as claimed in claim 2, wherein second DPLL circuit comprises:
a second phase detector to receive the internal low-noise oscillator signal, an output of the second feedback circuit and the first DPLL output signal, the second phase detector to generate a second phase detector output based on a comparison of the internal low-noise oscillator signal, the output of the second feedback circuit and the first DPLL output signal;
a second adder to receive input from the output of the second phase detector and from a delayed version of the first DPLL output signal;
a second loop filter to receive the output of the second adder and to implement a frequency-domain filter operation; and
a second digitally-controlled oscillator (DCO) to receive input from the second loop filter and to generate a second DCO output based on the output of the second loop filter, the second DCO output to be input to the second adder.

5. The device as claimed in claim 4, wherein the second loop filter comprises a low-pass filter.

6. The device as claimed in claim 4, wherein the divider circuit comprises:
a hardware divider to generate a divided version of the first DPLL output signal, and
an adder to receive input from the output of the hardware divider and from the local oscillator signal and to generate the divided output clock signal.

7. The device as claimed in claim 6, wherein the divider circuit comprises dividing the first DPLL output by an integer value based on a register setting.

8. The device as claimed in claim 4, wherein the delayed version of the first DPLL output signal to be based on a programmable delay value.

9. A device comprising:
a phase acquisition circuit to receive a reference clock, a low-noise oscillator signal and a local oscillator signal, the phase acquisition circuit to generate a delayed version of the local oscillator signal, and the phase acquisition circuit to sample the reference clock with the delayed local oscillator signal to generate an internal reference signal and the phase acquisition circuit to sample the low-noise oscillator signal with the delayed local oscillator signal to generate an internal low-noise oscillator signal, and the phase acquisition circuit to sample the local oscillator signal with a delayed version of the local oscillator signal to generate an internal local oscillator signal;
a first feedback circuit;
a second feedback circuit; and
a divider circuit,
wherein the first feedback circuit to receive the internal reference signal and the first feedback circuit comprising:
a first digital phase-locked loop (DPLL) circuit, the first DPLL circuit to receive the internal reference signal and to generate a first DPLL output signal,
wherein the second feedback circuit to receive the internal low-noise oscillator signal and a sampled version of the internal local oscillator signal, the second feedback circuit comprising:
a second DPLL circuit, the second DPLL circuit to receive the internal low-noise oscillator signal and to generate a second DPLL output signal, and
wherein the divider circuit to receive the first DPLL output signal and the local oscillator signal and to generate a divided output clock signal.

10. The device as claimed in claim 9, wherein the first DPLL circuit comprises:
a first phase detector to receive the internal reference signal and the output of the first feedback circuit, the first phase detector to generate a first phase detector output based on a comparison of the internal reference signal and the output of the first feedback circuit;
a first loop filter to receive the first phase detector output and to implement a frequency-domain filter operation;
a first adder to receive a first input from the output of the first loop filter and to receive a second input from the second DPLL circuit; and
a first digitally-controlled oscillator (DCO) to receive input from the first adder and to generate a first DCO output based on the output of the first adder.

11. The device as claimed in claim 10, wherein the first loop filter comprises a low-pass filter.

12. The device as claimed in claim 10, wherein the second DPLL circuit comprises:
a second phase detector to receive the internal low-noise oscillator signal and to receive the first DPLL output, the second phase detector to generate a second phase detector output based on a comparison of the internal low-noise oscillator signal and the first DPLL output;
a second adder to receive input from the output of the second phase detector, from the output of a third phase detector and from the second DPLL output signal;
a second loop filter to receive the output of the second adder and to implement a frequency-domain filter operation; and
a second digitally-controlled oscillator (DCO) to receive input from the second loop filter and to generate a second DCO output based on the output of the second loop filter.

13. The device as claimed in claim 12, wherein the second loop filter comprises a low-pass filter.

14. The device as claimed in claim 12, wherein the divider circuit comprises:
a hardware divider to generate a divided version of the first DPLL output signal,
a delay circuit to generate a delayed version of the local oscillator signal, and
an adder to receive input from the output of the hardware divider and from the delayed version of the local oscillator signal and to generate the divided output clock signal.

15. The device as claimed in claim 14, wherein the hardware divider comprises dividing the first DPLL output by an integer value based on a register setting.

16. A method comprising:
detecting a first phase relationship between an input reference and a local oscillator signal to generate an internal reference signal;
detecting a second phase relationship between a low-noise oscillator signal and the local oscillator signal to generate an internal low-noise oscillator signal;
detecting a third phase relationship between a delayed version of a local oscillator signal and the local oscillator signal;
generating a first digital phase-locked-loop (DPLL) output based on the first phase relationship;
generating a second DPLL output based on the second phase relationship and based on the third phase relationship; and
generating a divided output clock based on the first DPLL output.

17. The method as claimed in claim 16, wherein generating a first DPLL output comprises:
detecting a phase relationship between the internal reference signal and the first DPLL output;
filtering the phase relationship in a loop filter circuit, and
generating the first DPLL output based on the output of the loop filter.

18. The method as claimed in claim 16, wherein generating a second DPLL output comprises:
detecting a phase relationship between the internal low-noise oscillator signal and the second DPLL output;
filtering the phase relationship in a loop filter circuit; and
generating the second DPLL output based on the output of the loop filter.

19. The method as claimed in claim 16, wherein generating a divided output clock comprises:
dividing the first DPLL output, and
combining the oscillator input and the divided first DPLL output to generate the divided output clock.

20. The method as claimed in claim 16, wherein dividing the first DPLL output comprises dividing the first DPLL output by an integer value based on a register setting.
